(19) United States
(12) Patent Application Publication
(10) Pub. No.: US 2024/0071935 A1
(43) Pub. Date: Feb. 29, 2024

(54) GLASS DIE-TO-DIE BRIDGE AND INTERPOSER FOR DIE FIRST ARCHITECTURE

(71) Applicant: Intel Corporation, Santa Clara, CA (US)

(72) Inventors: Brandon C. MARIN, Gilbert, AZ (US); Ravindranath V. MAHAJAN, Chandler, AZ (US); Srinivas V. PIETAMBARAM, Chandler, AZ (US); Gang DUAN, Chandler, AZ (US); Suddhasattwa NAD, Chandler, AZ (US); Jeremy D. ECTON, Gilbert, AZ (US)

(21) Appl. No.: 17/895,965

(22) Filed: Aug. 25, 2022

(51) Int. Cl. H01L 23/538; H01L 21/48; H01L 21/56; H01L 23/00; H01L 23/15; H01L 23/31; H01L 23/48

(52) U.S. Cl. CPC H01L 23/5381; H01L 21/4846; H01L 21/565; H01L 23/15; H01L 23/3121; H01L 23/481; H01L 23/5386; H01L 24/08; H01L 24/80; H01L 2224/08225; H01L 2224/80894; H01L 2224/80895

(57) ABSTRACT

Embodiments disclosed herein include electronic packages. In an embodiment, the electronic package comprises a first substrate, where the first substrate comprises glass, and a second substrate over the first substrate, where the second substrate comprises glass. In an embodiment, electrically conductive routing is provided in the second substrate. In an embodiment, a first die is over the second substrate, and a second die is over the second substrate. In an embodiment, the electrically conductive routing electrically couples the first die to the second die.

### TECHNICAL FIELD

Embodiments of the present disclosure relate to electronic packages, and more particularly to electronic packages with a glass bridge architecture.

### BACKGROUND

In semiconductor packaging applications, the use of multiple die tiles is becoming more common. Die tiling allows for higher die yield since large area dies are not needed. The individual tiles are then coupled together using some sort of bridge architecture. In one instance, a silicon bridge may be embedded in the package substrate. The silicon bridge has high density routing in order to provide electrical interconnects between the die tiles.

However, as the number of die tiles increase, the number of bridges also increases. The complexity of assembling multiple bridges in an electronic package is high. Furthermore, solder interconnects between the bridge and the die tiles results in suboptimal electrical performance.

### BRIEF DESCRIPTION OF THE DRAWINGS

FIG. 1 is a cross-sectional illustration of an electronic package with an embedded bridge that is coupled to the dies with a solder interconnect.

FIG. 2 is a cross-sectional illustration of an electronic package with a bridge fabricated in a glass substrate layer that includes hybrid bonding to the dies, in accordance with an embodiment.

FIG. 3A is a cross-sectional illustration of a glass substrate used in an electronic package, in accordance with an embodiment.

FIG. 3B is a cross-sectional illustration of the glass substrate after a second glass substrate is formed with electrically conductive routing, in accordance with an embodiment.

FIG. 3C is a cross-sectional illustration of the electronic package after dies are bonded to the second glass substrate with a hybrid bonding architecture, in accordance with an embodiment.

FIG. 3D is a cross-sectional illustration of the electronic package after a mold layer is provided around the dies, in accordance with an embodiment.

FIG. 3E is a cross-sectional illustration of the electronic package after routing is provided in and over the mold layer, in accordance with an embodiment.

FIG. 3F is a cross-sectional illustration of the electronic package after buildup layers and second level interconnect (SLI) pads are formed, in accordance with an embodiment.

FIG. 4 is a cross-sectional illustration of an electronic system with an electronic package that includes a bridge integrated into a glass substrate, in accordance with an embodiment.

FIG. 5 is a schematic of a computing device built in accordance with an embodiment.

### EMBODIMENTS OF THE PRESENT DISCLOSURE

Described herein are electronic packages with a glass bridge architecture, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

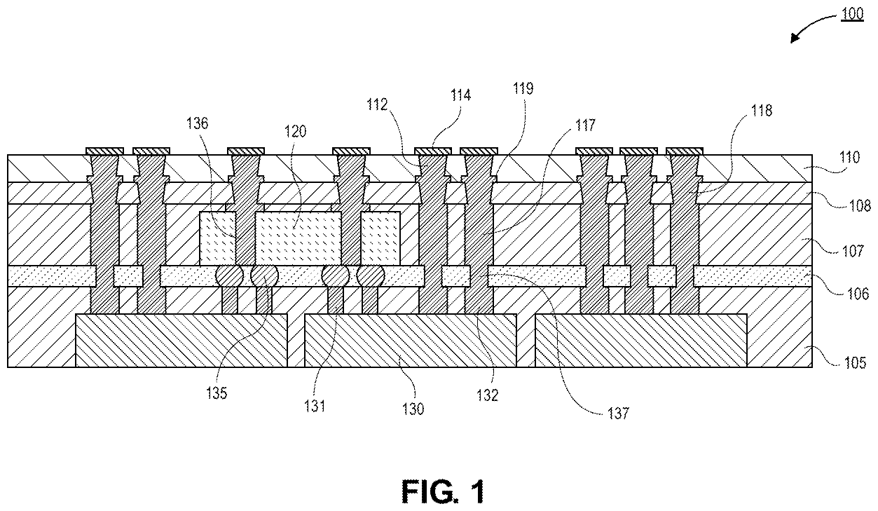

As noted above, advanced electronic packaging architectures are moving towards solutions with disaggregated dies. In order to couple together the dies (which are sometimes referred to as die tiles, chiplets, or the like), a die-to-die interconnect architecture is needed. In some instances an embedded bridge is used to enable the die-to-die connection. The embedded bridge enables localized high density routing, only where the high density routing is necessary. The remainder of the package substrate can include coarser line and space dimensions. An example of such a structure is shown in FIG. 1.

As shown in FIG. 1, the electronic package 100 comprises a plurality of dies 130 that may be embedded in a mold layer 105. The dies 130 may be die chiplets or die tiles that are coupled together by one or more bridges 120. The dies 130 may be coupled to the bridge 120 by vias 131 through the mold layer 105 and interconnects 135 in a layer 106. The interconnects 135 are often solder interconnects. As such, there is a relatively long electrical path (e.g., die 130, to via 131, to interconnect 135, to bridge 120) between the die 130 and the bridge 120. A similarly long path is required to go from the bridge 120 back to the second die 130. In addition to having a long length, the interconnect 135 may result in decreased electrical performance compared to a copper bump or the like. In some instances, electrical connections through the bridge 120 may be formed with vias 136.

The dies 130 may also be coupled to pads 119 on an opposite side of the electronic package 100. Pads 119 may be coupled to solder 114 by vias 112 through a solder resist layer 110. Buildup layers 107 and 108 may also comprise conductive routing 117 and 118. The conductive routing 117 and 118 may have line widths and spacings that are greater than line widths and spacings on the bridge 136. The dies 130 may be coupled to the conductive routing 117 and 118 by vias 137 and bumps 132.

As shown, the dies 130 only have electrical coupling on a single side of the dies 130. In the illustrated configuration shown in FIG. 1, the top side of the dies 130 include electrical connections. As such a truly three dimensional (3D) interconnect architecture is not provided in the electronic package 100. Additionally, the bridge 120 is provided between the dies 130 and the second level interconnects (SLIs) such as the solder 114.

However, in embodiments described herein, a truly 3D interconnect architecture is provided. That is, the bridge structure may be provided on a first side of the dies, and the SLIs may be provided on a second side of the dies. In order to make connections between the two sides, through silicon vias (TSVs) may be provided through the dies. In a particular embodiment, the electrical performance is also improved by reducing the interconnect distance between the die and the bridge structure. Further, a hybrid bonding solution may be used in order to avoid the use of solder between the bridge structure and the die.

Generally, the bridge structure described herein is formed in a glass layer. The glass layer provides a highly planar surface that is able to be patterned to form fine line/spacing dimensions. For example, line/spacing dimensions of embodiments disclosed herein may be approximately Sum/Sum or less, or approximately 2 μm/2 μm or less. As used herein, “approximately” may refer to a range of values within ten percent of the stated value. For example, approximately 5 μm may refer to a range between 4.5 μm and 5.5 μm.

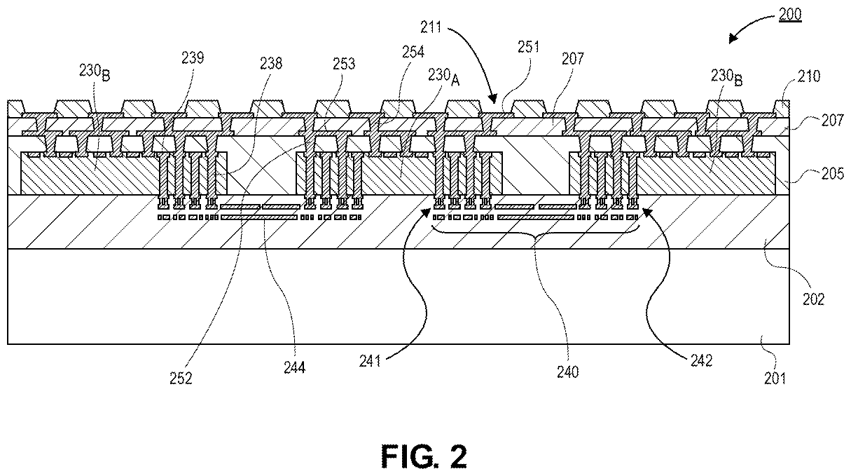

Referring now to FIG. 2, a cross-sectional illustration of an electronic package 200 is shown, in accordance with an embodiment. In an embodiment, the electronic package 200 comprises a first substrate 201. In an embodiment, the first substrate 201 may comprise glass. In an embodiment, a second substrate 202 is provided over the first substrate 201. The second substrate 202 may also comprise glass. In an embodiment, the second substrate 202 may be formed from a plurality of sub-layers (not shown). The sub-layers may be deposited and patterned in order to form a bridge structure 240. The bridge structure 240 may include electrically conductive routing 244. The conductive routing 244 of the bridge structure 240 may include one or more layers. While shown as having three layers in FIG. 2, it is to be appreciated that five or more layers of conductive routing 244 may be included in the second substrate 202.

In an embodiment, the second substrate 202 may comprise a glass formulation that is compatible with laser assisted patterning processes. A laser assisted patterning process may use a laser to expose regions of the second substrate 202. The exposed regions undergo a microstructure and/or phase change. The change in the microstructure and/or phase renders the exposed regions more susceptible to an etching chemistry than the unexposed regions. After the laser assisted patterning, electrically conductive routing 244 (e.g., pads, traces, vias, etc.) may be plated onto the second substrate 202. By repeating the laser assisted patterning process multiple times, a stack of conductive routing 244 embedded in glass can be provided. In an embodiment, the electrically conductive routing 244 may be high density routing in order to electrically couple dies 230 together. In a particular embodiment, line/space dimensions of the conductive routing 244 may be approximately 5 μm/5 μm or less, or approximately 2 μm/2 μm or less.

In an embodiment, a thickness of the first substrate 201 may be thicker than a thickness of the second substrate 202. However, in other embodiments, the first substrate 201 may have a thickness equal to or less than a thickness of the second substrate 202. Additionally, while both the first substrate 201 and the second substrate 202 comprise glass, a first glass formulation of the first substrate 201 may be different than a second glass formulation of the second substrate 202. For example, the first substrate 201 may be a glass formulation that is not compatible with laser assisted patterning, and the second substrate 202 may be compatible with laser assisted patterning. However, in other embodiments, the first substrate 201 and the second substrate 202 may have the same glass formulation. In some embodiments, a distinct seam may be observed between the first substrate 201 and the second substrate 202. In other embodiments, there may not be a seam between the first substrate 201 and the second substrate 202.

In an embodiment a first die 230A may be electrically coupled to second dies 230B by the bridge structures 240. Particularly, a first end 241 of the bridge structures 240 may be coupled to the first die 230A, and a second end 241 of the bridge structures 240 may be coupled to the second dies 230B. In contrast to the architecture shown in FIG. 1, the dies 230A and 230B may be directly coupled to the bridge structures 240. For example, a hybrid bonding process may be used to couple the dies 230 to the conductive routing 244 of the bridge structures 240. As used herein, “hybrid bonding” may refer to two structures that are bonded together with a first interface and a second interface. The first interface may be substantially coplanar with the second interface. For example, the hybrid bonding in FIG. 2 may include copper-to-copper bonding at a first interface and die-to-glass bonding at a second interface. The die-to-glass bonding may be a silicon-to-glass bond in some embodiments. The use of hybrid bonding eliminates the use of solder and reduces the interconnect length between the dies 230 and the bridge structures 240. As such, the electrical performance of the electronic package 200 is improved.

In an embodiment, the first die 230A and the second dies 230B may be chiplets or die tiles. That is, the first die 230A and the second dies 230B may be substantially similar types of dies that are communicatively coupled to each other in order to provide enhanced computing power without the need for a large area die. As such, die 230 yield can be improved without sacrificing performance. In an particular embodiment, the dies 230A and 230B are compute dies, such as processors, graphics processors, ASICs, systems on a chip (SoC), or any other type of die. Additionally, while shown as substantially similar in FIG. 2, in some embodiments, the first die 230A may be different than the second dies 230B. Furthermore, the second dies 230B may be different from each other in some instances.

While three dies 230 are shown in FIG. 2, it is to be appreciated that any number of dies 230 may be interconnected with bridge structures 240. In contrast to embedded bridge architectures, the use of bridge structures 240 that are fabricated on/in the second substrate 202 allows for greater scaling. That is, embedded bridge architectures require the placing and connecting of multiple bridge substrates, whereas embodiments disclosed herein allow for a single substrate to be used to connect many dies 230. Accordingly, yield and performance may both be improved by using embodiments described herein.

In an embodiment, the dies 230 may include TSVs 238. The TSVs 238 provide electrical coupling between the front and backside surface of the dies 230. For example, the TSVs 238 may couple the bridge structure 240 to pads 239 on an opposite side of the dies 230. The use of TSVs 238 allows for truly 3D interconnect architectures in the electronic package 200.

In an embodiment, the dies 230 may be embedded in a mold layer 205. The mold layer 205 may be any organic material that is suitable for molding. For example, a low viscosity buildup film may be used for the mold layer 205. In an embodiment, the mold layer 205 surrounds sidewall surfaces and top surfaces of the dies 230. That is, a thickness of the mold layer 205 may be greater than a thickness of the dies 230. In an embodiment, vias 252 pass through the mold layer 205 in order to provide electrical access to the pads 239 on the dies 230.

In an embodiment, one or more buildup layers 207 may be provided over the mold layer 205. The buildup layers 207 may include electrically conductive routing (e.g., pads 251, vias 254, traces 253, and the like). The electrically conductive routing may be fabricated using standard electronic package assembly processes. In some embodiments, the vias 254 may have tapered sidewalls typical of laser ablation patterning of the buildup layers 207. The conductive routing in the buildup layers 207 may provide fanning out of the interconnects. The fan-out architecture may end at SLI pads 251. In an embodiment, the SLI pads 251 may be surrounded by a solder resist layer 210. Solder resist openings 211 may be provided in order to expose the surfaces of the SLI pads 251. While not shown, it is to be appreciated that one or more surface finish layers may be provided over the SLI pads 251. For example, a surface finish comprising nickel, palladium, and gold may be used in some embodiments.

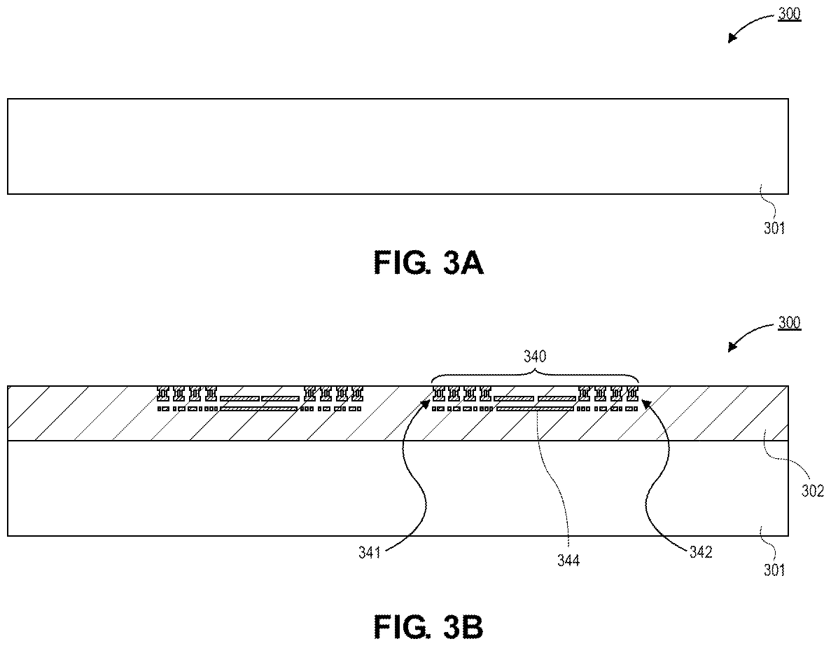

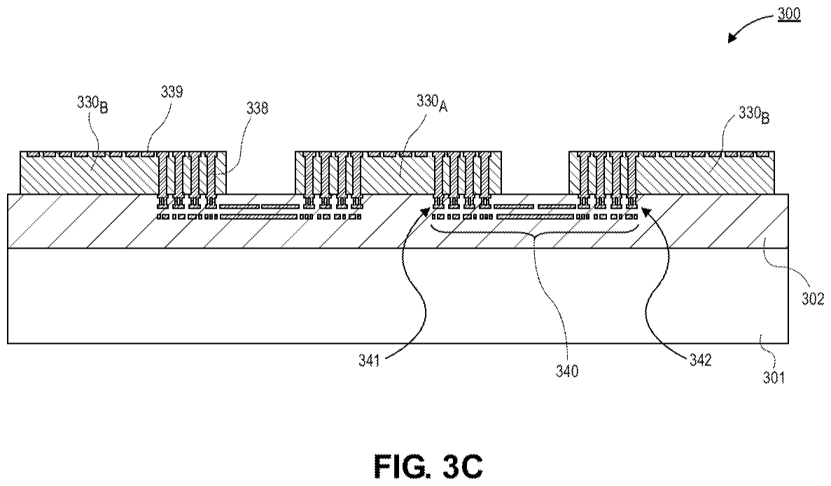

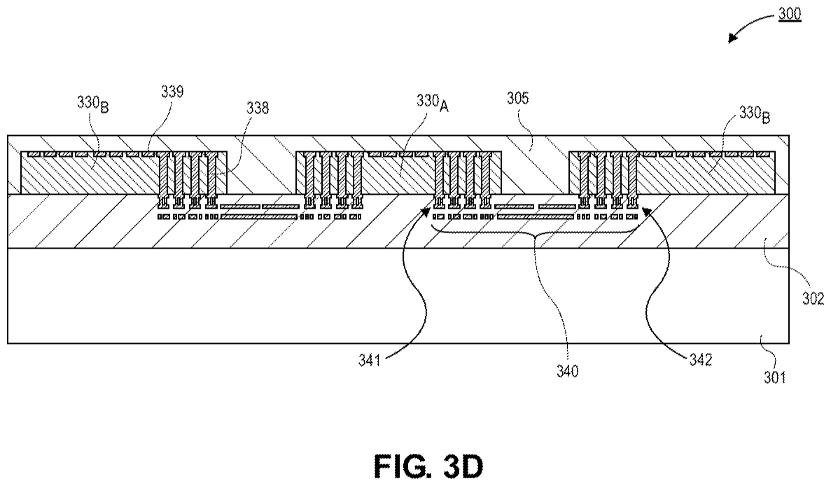

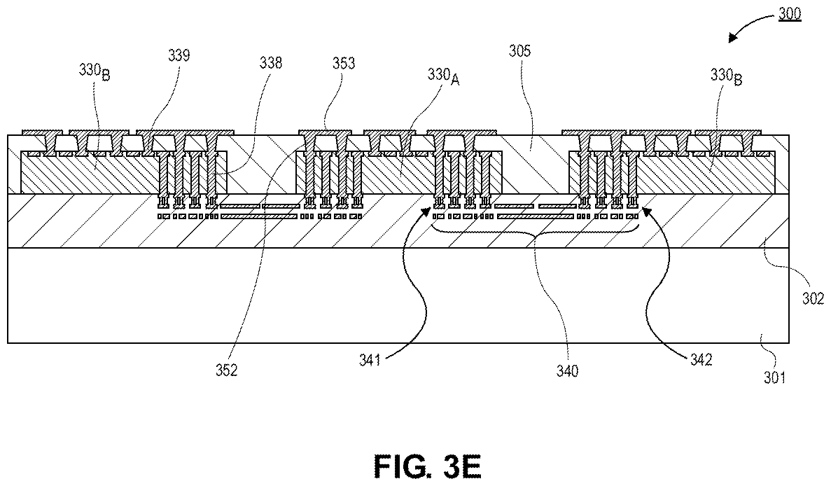

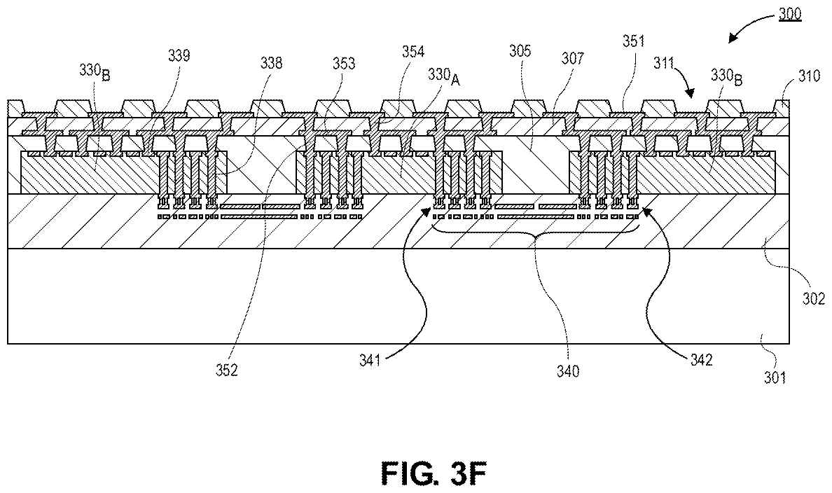

Referring now to FIGS. 3A-3F, a series of cross-sectional illustrations depicting a process for forming an electronic package 300 is shown, in accordance with an embodiment. In an embodiment, the electronic package 300 may be substantially similar to the electronic package 200 described above with respect to FIG. 2. For example, the electronic package 300 may have 3D interconnect architectures with bridge structures formed in a glass substrate layer.

Referring now to FIG. 3A, a cross-sectional illustration of the electronic package 300 at a stage of manufacture is shown, in accordance with an embodiment. In an embodiment, the electronic package 300 may comprise a first substrate 301. In an embodiment, the first substrate 301 may comprise glass. More particularly, the first substrate 301 may comprise substantially all glass in some embodiments. The first substrate 301 may be a glass panel. That is, multiple electronic packages 300 may be fabricated on the single first substrate 301. However, for simplicity, a single electronic package 300 is shown in FIGS. 3A-3F. In an embodiment, the first substrate 301 may have any suitable thickness. For example, the first substrate 301 may have a thickness that is approximately 100 μm to approximately 5,000 μm. Though thinner or thicker first substrates 301 may also be used in some embodiments. The first substrate 301 may have any glass formulation. For example, the first substrate 301 may comprise a fused silica glass or a borosilicate glass. While not required (since there may not be any patterning in the first substrate 301), the first substrate 301 may be compatible with laser assisted patterning processes, such as those described in greater detail above.

Referring now to FIG. 3B, a cross-sectional illustration of the electronic package 300 after a second substrate 302 is formed over the first substrate 301 is shown, in accordance with an embodiment. In an embodiment, the second substrate 302 may also comprise glass. That is, the second substrate 302 may comprise substantially all glass. In some embodiments, the second substrate 302 may be a different glass formulation than the first substrate 301. In other embodiments, the second substrate 302 may comprise the same glass formulation as the first substrate 301. While a seam is shown at the interface between the first substrate 301 and the second substrate 302, it is to be appreciated that in some embodiments the interface between the first substrate 301 and the second substrate 302 may be seamless. For example, the first substrate 301 and the second substrate 302 may visually appear to be a single combined substrate. In an embodiment, a thickness of the first substrate 301 may be greater than a thickness of the second substrate 302. In other embodiments, the second substrate 302 may have a thickness substantially similar to or greater than the first substrate 301.

In a particular embodiment, the second substrate 302 may be a glass formulation that is compatible with laser assisted patterning operations, such as those described in greater detail above. In an embodiment, the second substrate 302 may comprise a plurality of sub-layers. One or more of the sub-layers may be patterned and plated in order to form an embedded bridge structure 340. For example, three sub-layers are shown in FIG. 3B. Though, it is to be appreciated that one or more sub-layers may be patterned in order to form a bridge structure 340 with any number of routing layers.

In an embodiment, the bridge structure 340 may comprise electrically conductive routing 344. For example, the electrically conductive routing 344 may include traces, pads, vias, and the like. The conductive routing 344 may be considered high density routing. That is, the line/space dimensions of the conductive routings 344 may be approximately 5 μm/5 μm or less, or approximately 2 μm/2 μm or less. The fine line/space dimensions are enabled, at least in part, by the extremely flat surface of the first substrate 301 and the second substrate 302. The flat surfaces are characteristic of glass substrates. In the illustrated embodiment, a pair of two bridge structures 340 is shown for illustrative purposes. However, it is to be appreciated that any number of bridge structures 340 may be formed. Further, it is to be appreciated that forming more bridge structures 340 does not significantly complicate the manufacture of the electronic package 300. This is because there is no need to individually place multiple discreet bridge substrates, as is currently the case.

In an embodiment, the bridge structures 340 may include a first end 341 and a second end 342. Subsequent to formation of the bridge structures 340, the first end 341 may be coupled to a first die and the second end 342 may be coupled to a second die. As such, die-to-die interconnects are provided through the bridge structures 340 in the second substrate 302.

Referring now to FIG. 3C, a cross-sectional illustration of the electronic package 300 after a first die 330A and second dies 330B are attached to the second substrate 302 is shown, in accordance with an embodiment. While labeled as the first die 330A and the second dies 330B, it is to be appreciated that the first die 330A may be substantially similar to the second dies 330B in some embodiments. In other embodiments, the first die 330A may be different than the second dies 330B. In a particular embodiment, the first die 330A and the second dies 330B are chiplets or die tiles that are electrically coupled to each other through the bridge structures 340. First ends 341 of the bridge structures 340 may be coupled to the first die 330A and second ends 342 of the bridge structures 340 may be coupled to the second dies 330B. The dies 330 may be compute dies, such as processors, graphics processors, ASICs, SoCs, or the like. One or more of the dies 330 may also be memory dies in some embodiments.

In an embodiment, the dies 330 may comprise TSVs 338. The TSVs 338 provide electrical connections between a bottom surface and a top surface of the dies 330. For example, the bottom of the dies 330 that interface with the second substrate 302 may be electrically coupled to pads 339 on a top surface of the dies 330. The pads 339 are shown as having top surfaces that are coplanar with a top surface of the dies 330. In other embodiments, the pads 339 may be bumps that extend up from the top surface of the dies 330. The presence of the TSVs 338 enable 3D interconnect architectures in the electronic package 300.

In an embodiment, the dies 330 may be coupled to the second substrate 302 with a hybrid bonding process. In a hybrid bonding process, the TSVs 338 (or bottom pads (not shown)) are directly coupled to the pads of the bridge structure 340. Such a copper-to-copper bond may be formed with a solid state diffusion process. Additionally, a second interface may include the die-to-glass interface. The die-to-glass interface may be a silicon-to-glass bond in some embodiments. The second interface may also be formed with a diffusion bonding process or the like. As such, the hybrid bond includes at least two different types of bonding along coplanar interfaces.

Referring now to FIG. 3D, a cross-sectional illustration of the electronic package 300 after a mold layer 305 is applied over the dies 330 is shown, in accordance with an embodiment. The mold layer 305 may be any suitable molding material. For example, the mold layer 305 may be an organic molding material, such as a low viscosity buildup film or an epoxy material. In an embodiment, the mold layer 305 may substantially embed the dies 330 and be provided over the second substrate 302. That is, the mold layer 305 may be provided over sidewalls of the dies 330 and over top surfaces of the dies 330. The mold layer 305 may have a thickness that is greater than a thickness of the dies 330.

Referring now to FIG. 3E, a cross-sectional illustration of the electronic package 300 after routing is provided in the mold layer 305 is shown, in accordance with an embodiment. In an embodiment, the routing 305 may include vias 352 that land on the pads 339 of the dies 330. The openings for the vias 352 may be formed with a laser ablation process. As such, the vias 352 may have a tapered cross-section. For example, the shape of the vias 352 may be trapezoidal, and bottom widths of the vias 352 may be smaller than top widths of the vias 352. In an embodiment, conductive routing 353 may be provided over the top surface of the mold layer 305. The conductive routing 353 may include traces, pads, and the like. In an embodiment, the vias 352 and the conductive routing 353 may be plated with any suitable deposition process, such as electrolytic plating, electroless plating, chemical vapor deposition (CVD), sputtering, or the like.

Referring now to FIG. 3F, a cross-sectional illustration of the electronic package 300 after one or more buildup layers 307 are formed is shown, in accordance with an embodiment. In the illustrated embodiment, a single buildup layer 307 is shown for simplicity. However, it is to be appreciated that any number of buildup layers 307 may be used in order to enable the desired fan-out pattern to the SLI pads 351. In an embodiment, the buildup layers 307 may be deposited over the mold layer 305 with a lamination process or the like. The buildup layers 307 may then be patterned with a laser ablation process or the like. The patterning may be used to form vias 354, traces, pads, etc. that couple the conductive routing 353 to the SLI pads 351. In a particular embodiment, the vias 354 may have a trapezoidal cross-section with an end that faces the dies 330 being narrower than an end that faces away from the dies 330. In an embodiment, a solder resist layer 310 may be applied over the topmost buildup layer 307. The solder resist layer 310 may be applied with a lamination process or the like. In an embodiment, solder resist openings 311 may be provided through the solder resist layer 310 in order to expose the SLI pads 351. In some embodiments, a surface finish (e.g., nickel, palladium, gold) may be applied over the exposed surfaces of the SLI pads 351.

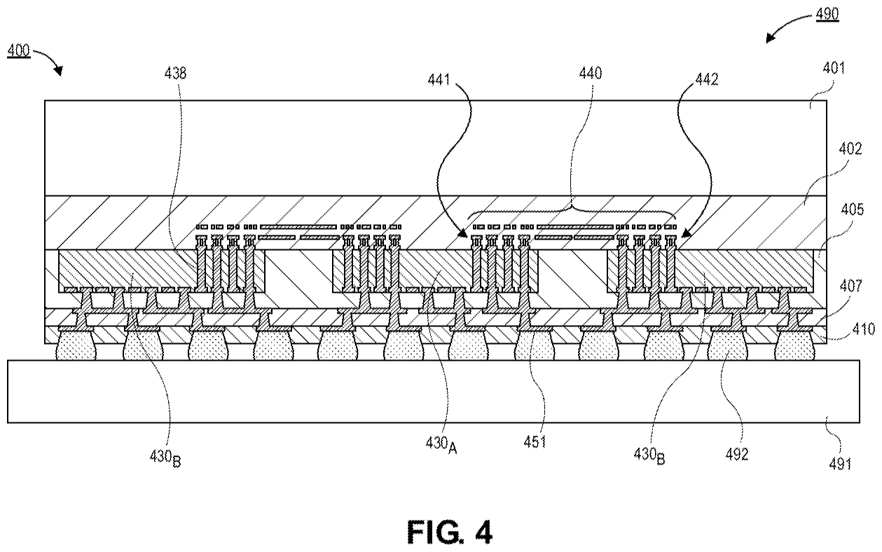

Referring now to FIG. 4, a cross-sectional illustration of an electronic system 490 is shown, in accordance with an embodiment. In an embodiment, the electronic system 490 may comprise a board 491, such as a printed circuit board (PCB). The board 491 may be electrically and mechanically coupled to an electronic package 400 by interconnects 492. The interconnects 492 shown in FIG. 4 are solder balls, but it is to be appreciated that any SLI architecture may be used for the interconnects 492. The interconnects 492 may be coupled to pads 451 surrounded by a solder resist layer 410.

In an embodiment, the electronic package 400 may comprise a first substrate 401. The first substrate 401 may comprise glass. A second substrate 402 may be provided under the first substrate 401. The second substrate 402 may also include glass. In an embodiment, a bridge structure 440 is embedded in the second substrate 402. The bridge structure 440 may include a first end 441 and a second end 442. The first end 441 may be electrically coupled to a first die 430A and the second end 442 may be electrically coupled to a second die 430B. In an embodiment, the dies 430 are coupled to the bridge structure 440 using a hybrid bonding architecture.

In an embodiment, the dies 430 may include TSVs 438. The TSVs 438 may enable 3D interconnect architectures in the electronic package 400. For example, the dies 430 may be between the bridge structure 440 and the SLI pads 451. In an embodiment, a mold layer 405 embeds the dies 430. Additionally, one or more buildup layers 407 may be provided between the mold layer 405 and a solder resist layer 410. Conductive routing through the mold layer 405 and the one or more buildup layer 407 couple the dies 430 to the SLI pads 451.

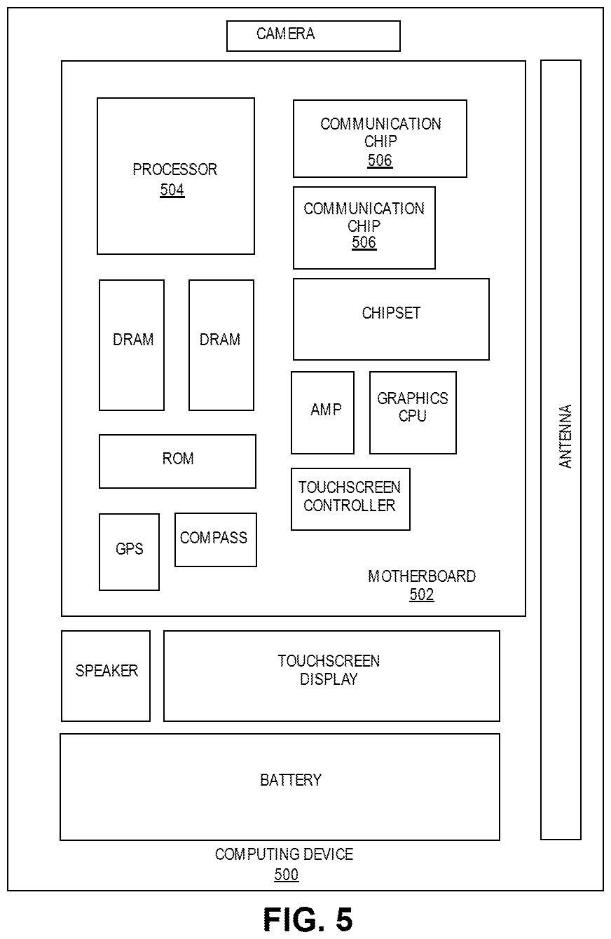

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor may be part of an electronic system that includes a package substrate with a bridge structure embedded in a glass substrate layer over the dies, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip may be part of an electronic system that includes a package substrate with a bridge structure embedded in a glass substrate layer over the dies, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a first substrate, wherein the first substrate comprises glass; a second substrate over the first substrate, wherein the second substrate comprises glass; electrically conductive routing in the second substrate; a first die over the second substrate; and a second die over the second substrate, wherein the electrically conductive routing electrically couples the first die to the second die.

Example 2: the electronic package of Example 1, wherein the first die and the second die are coupled to the second substrate with hybrid bonding.

Example 3: the electronic package of Example 2, wherein the hybrid bonding includes a copper-to-copper bond and a glass-to-silicon bond.

Example 4: the electronic package of Examples 1-3, wherein the electrically conductive routing includes line width dimensions of 2 μm or less and spacings between lines of 2 μm or less.

Example 5: the electronic package of Examples 1-4, wherein the electrically conductive routing includes two or more layers of routing in the second substrate.

Example 6: the electronic package of Examples 1-5, further comprising: a mold layer around the first die and the second die.

Example 7: the electronic package of Example 6, further comprising: a buildup layer over the mold layer.

Example 8: the electronic package of Example 7, further comprising: routing from the first die and the second die to a surface of the buildup layer.

Example 9: the electronic package of Example 8, further comprising: a solder resist over the buildup layer.

Example 10: the electronic package of Examples 1-9, wherein the first substrate is thicker than the second substrate.

Example 11: the electronic package of Examples 1-10, wherein the first die and the second die include through silicon vias (TSVs).

Example 12: the electronic package of Example 11, wherein the TSVs are electrically coupled to the electrically conductive routing in the second substrate.

Example 13: the electronic package of Examples 1-12, wherein the first substrate and/or the second substrate comprise fused silica glass or borosilicate glass.

Example 14: an interposer, comprising: a first substrate, wherein the first substrate comprises glass; a second substrate over the first substrate, wherein the second substrate comprises glass; and electrically conductive routing in the second substrate, wherein the electrically conductive routing has line widths of 2 μm or less and line spacings of 2 μm or less.

Example 15: the interposer of Example 14, wherein the first substrate is thicker than the second substrate.

Example 16: the interposer of Example 14 or Example 15, wherein the first substrate comprises a first glass formulation, and wherein the second substrate comprises a second glass formulation that is different than the first glass formulation.

Example 17: the interposer of Example 16, wherein the second glass formulation is compatible with laser assisted patterning operations.

Example 18: the interposer of Examples 14-17, wherein the electrically conductive routing comprises a first end and a second end.

Example 19: the interposer of Example 18, wherein the first end is coupled to a first die and the second end is coupled to a second die.

Example 20: the interposer of Example 19, wherein the first die and the second die are hybrid bonded to the second substrate.

Example 21: a method of forming an electronic package, comprising: providing a first substrate, wherein the first substrate comprises glass; forming a second substrate over the first substrate, wherein the second substrate comprises glass with electrically conductive routing; attaching a first die and a second die to the second substrate, wherein the first die is electrically coupled to a first end of the electrically conductive routing, and wherein the second die is electrically coupled to a second end of the electrically conductive routing; embedding the first die and the second die in a mold layer; and forming a buildup layer over the mold layer.

Example 22: the method of Example 21, wherein the first die and the second die are attached to the second substrate with a hybrid bonding architecture.

Example 23: the method of Example 21 or Example 22, wherein the first die and the second die comprise through silicon vias (TSVs).

Example 24: an electronic system, comprising: a board; and an electronic package coupled to the board, wherein the electronic package comprises: a substrate comprising glass, wherein electrically conductive routing is provided in the substrate; a first die over the substrate; and a second die over the substrate, wherein the first die is electrically coupled to the second die by the electrically conductive routing.

Example 25: the electronic system of Example 24, wherein the electrically conductive routing has line widths of 2 μm or less, and wherein the electrically conductive routing has line spacings of 2 μm or less.

What is claimed is:

1. An electronic package, comprising:
a first substrate, wherein the first substrate comprises glass;
a second substrate over the first substrate, wherein the second substrate comprises glass;
electrically conductive routing in the second substrate;
a first die over the second substrate; and
a second die over the second substrate, wherein the electrically conductive routing electrically couples the first die to the second die.

2. The electronic package of claim 1, wherein the first die and the second die are coupled to the second substrate with hybrid bonding.

3. The electronic package of claim 2, wherein the hybrid bonding includes a copper-to-copper bond and a glass-to-silicon bond.

4. The electronic package of claim 1, wherein the electrically conductive routing includes line width dimensions of 2 μm or less and spacings between lines of 2 μm or less.

5. The electronic package of claim 1, wherein the electrically conductive routing includes two or more layers of routing in the second substrate.

6. The electronic package of claim 1, further comprising:
a mold layer around the first die and the second die.

7. The electronic package of claim 6, further comprising:
a buildup layer over the mold layer.

8. The electronic package of claim 7, further comprising:
routing from the first die and the second die to a surface of the buildup layer.

9. The electronic package of claim 8, further comprising:
a solder resist over the buildup layer.

10. The electronic package of claim 1, wherein the first substrate is thicker than the second substrate.

11. The electronic package of claim 1, wherein the first die and the second die include through silicon vias (TSVs).

12. The electronic package of claim 11, wherein the TSVs are electrically coupled to the electrically conductive routing in the second substrate.

13. The electronic package of claim 1, wherein the first substrate and/or the second substrate comprise fused silica glass or borosilicate glass.

14. An interposer, comprising:
a first substrate, wherein the first substrate comprises glass;
a second substrate over the first substrate, wherein the second substrate comprises glass; and
electrically conductive routing in the second substrate, wherein the electrically conductive routing has line widths of 2 μm or less and line spacings of 2 μm or less.

15. The interposer of claim 14, wherein the first substrate is thicker than the second substrate.

16. The interposer of claim 14, wherein the first substrate comprises a first glass formulation, and wherein the second substrate comprises a second glass formulation that is different than the first glass formulation.

17. The interposer of claim 16, wherein the second glass formulation is compatible with laser assisted patterning operations.

18. The interposer of claim 14, wherein the electrically conductive routing comprises a first end and a second end.

19. The interposer of claim 18, wherein the first end is coupled to a first die and the second end is coupled to a second die.

20. The interposer of claim 19, wherein the first die and the second die are hybrid bonded to the second substrate.

21. A method of forming an electronic package, comprising:
providing a first substrate, wherein the first substrate comprises glass;
forming a second substrate over the first substrate, wherein the second substrate comprises glass with electrically conductive routing;
attaching a first die and a second die to the second substrate, wherein the first die is electrically coupled to a first end of the electrically conductive routing, and wherein the second die is electrically coupled to a second end of the electrically conductive routing;
embedding the first die and the second die in a mold layer; and
forming a buildup layer over the mold layer.

22. The method of claim 21, wherein the first die and the second die are attached to the second substrate with a hybrid bonding architecture.

23. The method of claim 21, wherein the first die and the second die comprise through silicon vias (TSVs).

24. An electronic system, comprising:
a board; and
an electronic package coupled to the board, wherein the electronic package comprises:
a substrate comprising glass, wherein electrically conductive routing is provided in the substrate;
a first die over the substrate; and
a second die over the substrate, wherein the first die is electrically coupled to the second die by the electrically conductive routing.

25. The electronic system of claim 24, wherein the electrically conductive routing has line widths of 2 μm or less, and wherein the electrically conductive routing has line spacings of 2 μm or less.
